(19) United States
(12) Patent Application Publication
(10) Pub. No.: US 2010/0084006 A1
(43) Pub. Date: Apr. 8, 2010

(54) Photovoltaic module

(75) Inventors: Ruey-Jong Shyu, Taoyuan Hsien (TW); Kuan-Liang Chen, Taoyuan Hsien (TW); Jen-Chih Lee, Taoyuan Hsien (TW); Yu-Chiao Tseng, Taoyuan Hsien (TW)

Correspondence Address: BACON & THOMAS, PLLC, 625 SLATERS LANE, FOURTH FLOOR, ALEXANDRIA, VA, 22314-1176, US

(73) Assignee: J Touch Corporation, Taoyuan Hsien (TW)

(21) Appl. No.: 12/314,870

(22) Filed: Dec. 18, 2008

(30) Foreign Application Priority Data
Oct. 6, 2008 (TW) 97138410

(51) Int. Cl. H01L 31/00; G04G 19/00

(52) U.S. Cl. 136/252; 368/205

(57) ABSTRACT

The present invention provides a photovoltaic module, comprising: a dye-sensitized solar cell; a supercapacitor, which is electrically connected to said dye-sensitized solar cell to store the electrical energy generated therefrom; and an electricity-consuming device, which is electrically connected to said dye-sensitized solar cell and said supercapacitor; wherein, when exposed to light, said dye-sensitized solar cell absorbs the light energy to transform into electrical energy, part of said electrical energy is to provide the operation of said electricity-consuming device, and the other part of said electrical energy is stored in said supercapacitor; in the circumstance of no light, said supercapacitor releases the stored electrical energy to said electricity-consuming device to maintain the operation thereof.

### BACKGROUND OF THE INVENTION

1. Field of the Invention

The present invention relates to a photovoltaic module, and more particularly to a photovoltaic module utilizing natural light or indoor light without any external power supply.

2. Description of the Related Art

Batteries, which are classified into primary battery and secondary battery, are the power supply of many electrical products. Primary battery includes dry cell, alkaline battery, mercury battery and etc. Secondary battery is the rechargeable battery, including lead-acid battery, nickel-cadmium battery, nickel-metal hydride battery, lithium battery and etc. Primary battery is discarded after use, and cannot be reused. Therefore, the primary battery is highly cost and the spent battery causes environmental problems such as environment pollution. For the issues of environment protection, the rechargeable secondary battery is employed. However, the capacity and lifetime of secondary battery require further improvement.

For the global energy problem, solar energy is considered to be the best substitute energy. Then the solar cell is designed to be used on the electrical products rely on sufficient light source (e.g. outdoor). In order to maintain a stable energy supply, the problems of unavailability under insufficient light or at night must be solved, so the design of energy storage unit is usually integrated on a solar cell system. The general energy storage unit includes lead-acid battery, nickel-cadmium battery, nickel-metal hydride battery, lithium battery and etc. Solar cells include silicon solar cell, thin film solar cell and the newly introduced dye-sensitized solar cell (DSSC). The absorption spectrum of DSSC is within the range of visible light. Besides the absorption of sun light at outdoor, DSSC can also absorb the indoor day light at a lower light intensity to generate electric energy, which makes DSSC suitable for indoor uses. DSSC relies on photoelectrochemical energy transfer mechanism to generate electricity, and its mechanism is different from that of silicon solar cell or thin film solar cell which uses silicon. DSSC is essentially constructed by upper and lower conductive substrates, which could be made of glass or flexible substrate. One of the substrates serves as electrode, which has metal oxide semiconductor such as nano-sized TiO₂ layer, while the other substrate serves as counter-electrode, which has platinum layer. Between these two electrodes, dye and electrolyte are loaded to form solar cells by appropriate packaging. When exposed to light, the dye releases electrons passing through the TiO₂ conductive layer and the conductive substrate, to generate electricity. The electrons then go to the counter-electrode, where they undergo the electrocatalytic activity of the platinum and redox reaction of the electrolyte, and return to the dye molecules to complete the cycle. Additionally, the material for making DSSC is abundant, and the manufacturing process requires no expensive vacuum coating equipments. Therefore, DSSC has the potential to greatly reduce the manufacturing cost. Since the manufacturing cost of DSSC is lower than that of silicon solar cell, DSSC is a novel solar cell having the potential for various applications.

Moreover, timing device such as clocks including wall clocks or table clocks, which usually use primary alkaline battery, needs to change battery after using about 1 year. The discarded batteries cause the problems of environment pollution and recycling. There are also solar cell clocks available on the market, which still have secondary batteries such as nickel-metal hydride batteries or lithium batteries as their main power source, while the solar cell is used as an auxiliary one, and limited by the disadvantage of insufficient power under low light intensity.

Most of the solar cells for consumer electronic products need to be charged and to store electricity. Nickel-metal hydride battery or nickel-cadmium battery is usually used to charge or store electricity. However, nickel-metal hydride battery has low tolerance for high temperature, while nickel-cadmium battery has the problem of environment pollution. Beside the above-mentioned rechargeable secondary batteries, some solar cell products use supercapacitor as storage unit to store and provide electricity. Supercapacitor utilizes the charge transfer process between electrode surface and electrolyte to store energy, which has the advantages of high electrical capacity, short recharging time and high discharging capability. The material for both electrodes of supercapacitor is porous nano-structure, which has extremely large surface (1000 to 2000 m²/g for 1 to 5 nm-diameter pores), and excellent electrical conductivity, and does not react with the electrolyte, to allow large quantity of charges to adsorb on the electrical surface then form capacitors of high capacity. Supercapacitor can be charged and discharged quickly, and have high power density, low degradation and long lifetime. Besides, the material of supercapacitor uses no heave metals, which can reduce the environment pollution.

Therefore, a novel photovoltaic module is desired, which could absorb light to generate electricity to maintain the function of electricity-consuming products at a lower light intensity (such as indoor day light or lamplight), or at sufficient light intensity (outdoor day light), and even under no light condition.

### SUMMARY OF THE INVENTION

It is one aspect of the present invention to provide a photovoltaic module. Said photovoltaic module essentially comprises: a dye-sensitized solar cell; a supercapacitor, which is electrically connected to said dye-sensitized solar cell to store the electrical energy generated therefrom; and an electricity-consuming device, which is electrically connected to said dye-sensitized solar cell and said supercapacitor. The module has below features:
1. Under sufficient light intensity, the dye-sensitized solar cell transforms light energy into electrical energy to provide electricity for the electricity-consuming device, and charge the supercapacitor at the same time. In the circumstance of no light, the supercapacitor could release the stored electrical energy to maintain the operation of electricity-consuming device, and therefore other supplemental power supply device (such as lithium battery or alkaline battery) is not needed. The photovoltaic module can continuously operate for a very long time, which improves the energy efficiency, and also eliminates the environmental problem from the spent batteries, and is economic and environment friendly.
2. Compared to other solar cells, dye-sensitized solar cells could also transform light energy into electrical energy at a low light intensity (such as indoor lamplight). With the use of supercapacitor, the photovoltaic module could also maintain the operation of electricity-consuming device at a low light intensity without using supplemental power supply device (such as lithium battery).
3. Supercapacitor has small size and high energy density. The capacity of a supercapacitor is more than tens of thousand folds of that of a conventional capacitor. Besides, supercapacitor has very long lifetime of about 500,000 charging and discharging cycles, which is 500 times of a lithium battery, and 1,000 times of a nickel-metal hydride battery or a nickel-cadmium battery, therefore supercapacitor has the advantages of both conventional capacitor and secondary battery. Moreover, to distinguish from general products using the fast charging and discharging characteristic of supercapacitor, the present invention also uses the slow charging and discharging characteristic of supercapacitor to achieve the efficacy of the present invention. Further more, as another important feature, the voltage and current generated by dye-sensitized solar cell under indoor lamplight is more suitable to be stored in the supercapacitor.
4. Besides the above-mentioned major components, the photovoltaic module of the present invention further includes a control unit, such as diode or power management IC, which is used to control the current between dye-sensitized solar cell and supercapacitor, and therefore provides the system a best operation performance.

According to the aspect of the present invention, the photovoltaic module of the present invention comprises: a dye-sensitized solar cell; a supercapacitor, which is electrically connected to said dye-sensitized solar cell to store the electrical energy generated therefrom; and an electricity-consuming device, which is electrically connected to said dye-sensitized solar cell and said supercapacitor; wherein, when exposed to light, said dye-sensitized solar cell absorbs the light energy to transform into electrical energy, and part of the said electrical energy is to provide the operation of said electricity-consuming device, and the other part of said electrical energy is stored in said supercapacitor; in the circumstance of no light, said supercapacitor releases the stored electrical energy to said electricity-consuming device to maintain the operation thereof.

Preferably, said dye-sensitized solar cell comprises a first electrode and a second electrode. Said first electrode comprises a first conductive layer, a platinum catalyst layer. Said first conductive layer comprises a first substrate and a first transparent conductive oxide to allow said platinum catalyst layer to adhere thereon. Said second electrode comprises a second conductive layer and a nano layer. Said second conductive layer comprises a second substrate and a second transparent conductive oxide. Said nano layer comprises an optical semiconductor oxide, a plurality of dye molecules and an electrolyte adhered on said optical semiconductor oxide.

Preferably, said first substrate and said second substrate are made of glass or flexible substrate (for example but not limited to stainless steel, titanium alloy, polyethylene terephthalate (PET) or polyethylene naphthalate (PEN)).

Preferably, said light absorbed by said dye-sensitized solar cell is sun light or the light from lighting device.

Preferably, said electricity-consuming device includes clock, night lamp and calculator.

Preferably, said photovoltaic module further includes a control unit, which is configured between said dye-sensitized solar cell and said supercapacitor to control the charging and discharging process thereof.

To sum up, the embodiment of the photovoltaic module of the present invention can be a clock using said photovoltaic module. The module essentially comprises: a dye-sensitized solar cell; a supercapacitor, which is electrically connected to said dye-sensitized solar cell to store the electrical energy generated from said dye-sensitized solar cell; and a clock, which is electrically connected to said dye-sensitized solar cell and said supercapacitor; wherein, when exposed to light, said dye-sensitized solar cell absorbs the light energy to transform into electrical energy, and part of said electrical energy is to provide the operation of said clock, and the other part of said electrical energy is stored in said supercapacitor; in the circumstance of no light, said supercapacitor releases the stored electrical energy to said clock to maintain the operation thereof. The clock of the present invention requires no external power supply device, and relies only on the electricity generated from the dye-sensitized solar cell. In the circumstance of no light, the supercapacitor could release the stored electricity to maintain the operation of the clock. The dye-sensitized solar cell further has the feature of transforming light energy into electrical energy at a low light intensity (such as indoor lamplight), and provides sufficient electricity to the clock without other supplemental power supply device. Preferably, the clock further includes a control unit (such as diode or power management IC) to control the current between said dye-sensitized solar cell and said supercapacitor, and provides a more efficient operation performance to the clock.

Moreover, besides the clock described in aforesaid embodiment, the preferred embodiment of the present invention can also be a night lamp or a calculator.

### BRIEF DESCRIPTION OF THE DRAWINGS

The above objects and advantages of the present invention will become more readily apparent to those ordinarily skilled in the art after reviewing the following detailed descriptions and accompanying drawings, in which:

FIG. 1 schematically shows the structure of a dye-sensitized solar cell;

FIG. 2A schematically shows the discharging process of a supercapacitor;

FIG. 2B schematically shows the charging process of a supercapacitor;

FIG. 3 schematically shows the connection of the photovoltaic module of the present invention;

FIG. 4 schematically shows the connection of the photovoltaic module of the present invention;

FIG. 5 schematically shows a first embodiment of table clock of the present invention;

FIG. 6 schematically shows a wall clock of the present invention;

FIG. 7 schematically shows a second embodiment of table clock of the present invention;

FIG. 8 schematically shows a third embodiment of table clock of the present invention;

FIG. 9 is the voltage plot during the discharging process of the supercapacitor according to the embodiment of the present invention.

FIG. 10 is the voltage plot of the photovoltaic module according to the embodiment of the present invention.

### DETAILED DESCRIPTION OF THE PREFERRED EMBODIMENT

As described above, the photovoltaic module 1 of the present invention comprises: a dye-sensitized solar cell 10; a supercapacitor 20, which is electrically connected to said dye-sensitized solar cell 10 to store the electrical energy generated from said dye-sensitized solar cell 10; and an electricity-consuming device 30, which is electrically connected to said dye-sensitized solar cell 10 and said supercapacitor 20; wherein, when exposed to light, said dye-sensitized solar cell 10 absorbs the light energy to transform into electrical energy, and part of the said electrical energy is to provide the operation of said electricity-consuming device 30, and the other part of said electrical energy is stored in said supercapacitor 20; in the circumstance of no light, said supercapacitor 20 releases the stored electrical energy to said electricity-consuming device 30 to maintain the operation thereof.

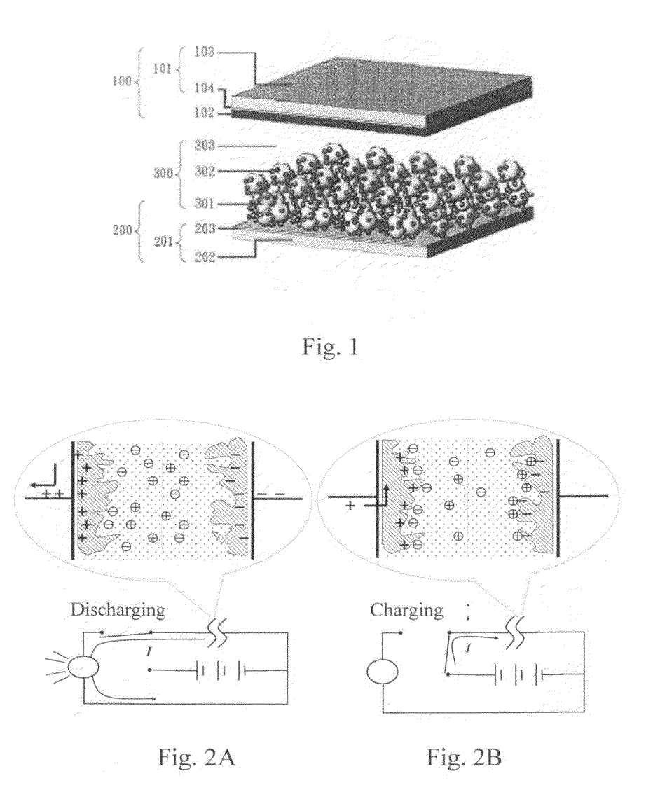

The dye-sensitized solar cell 10 of the present invention is schematically illustrated in FIG. 1, which comprises a first electrode 100, a second electrode 200. Said first electrode 100 comprises a first conductive layer 101 and a platinum catalyst layer 102. Said first conductive layer 101 comprises a first substrate 103 and a first transparent conductive oxide 104 to allow said platinum catalyst layer 102 to adhere on the surface of said first transparent conductive oxide 104. Said second electrode layer 200 comprises a second conductive layer 201 and a nano layer 300. Said second conductive layer 201 comprises a second substrate 202 and a second transparent conductive oxide 203. Said nano layer 300 comprises an optical semiconductor oxide 301, dye molecules 302and electrolyte 303 adhered on said optical semiconductor oxide 301. Said first substrate 103 and said second substrate 202 can be made of glass or flexible substrate. Said flexible substrate can be metal or polymer film. Said metal can be but not limited to stainless steel, titanium alloy and etc. The material of said polymer film can be but not limited to polyethylene terephthalate (PET), polyethylene naphthalate (PEN) and etc. Therefore, when the dye-sensitized solar cell 10 absorbs light energy, electrons are released to provide current to the external circuit through the optical semiconductor oxide and the conductive glass.

The supercapacitor 20 of the present invention is schematically illustrated in FIG. 2A and FIG. 2B, which uses the charge transfer process between the electrode surface and the electrolyte to store electrical energy. The supercapacitor 20 has the advantages of high capacity, short charging time and high discharging capability. The material for the electrodes of supercapacitor is porous nano structure, which has extremely high surface (1000 to 2000 m²/g for 1 to 5 diameter pores), excellent conductivity, and no reaction with the electrolyte to allow large quantity of charges to adsorb on the electrical surface to form capacitor of high capacity. Supercapacitor can release high current quickly for different products. The size of supercapacitor 20 is small, but its energy density is high, which is more than tens of thousands folds of a conventional capacitor. The lifetime of the supercapacitor 20 is very long, whose charging and discharging cycling is 500 to 1,000 times of that of a secondary battery. Besides, to be different from general products using the characteristic of fast charging and discharging of the supercapacitor 20, the present invention uses the characteristic of slow charging and discharging to achieve the efficacy of the present invention. Moreover, the voltage and current generated from dye-sensitized solar cell under indoor light is more suitable to use supercapacitor 20 as the storage unit.

Preferably, the electricity-consuming device 30 of the present invention is a small power electricity-consuming product such as clock, night lamp or calculator.

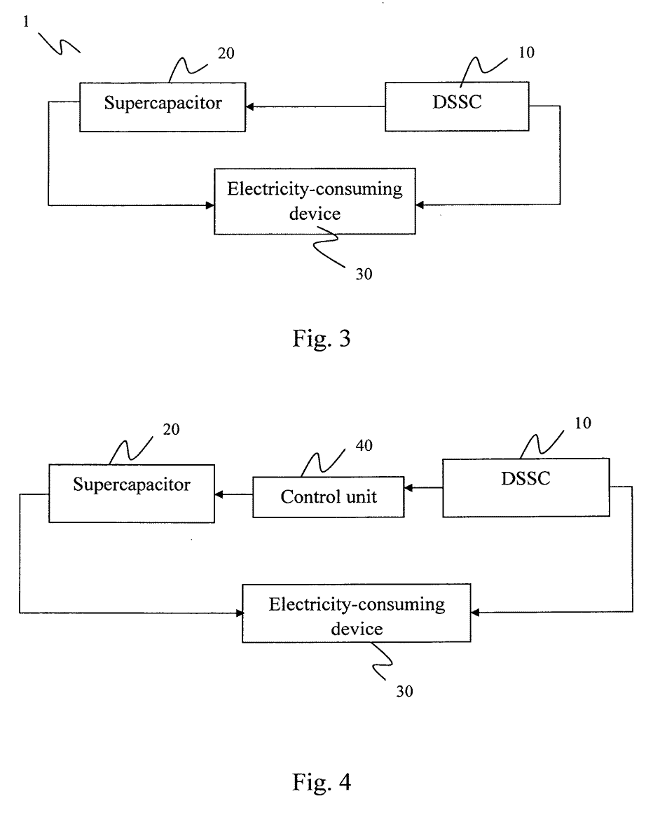

The connection of dye-sensitized solar cell 10, supercapacitor 20 and electricity-consuming device 30 in the photovoltaic module 1 of the present invention is schematically illustrated in FIG. 3. As shown in FIG. 3, when exposed to light, the dye-sensitized solar cell 10 transforms light energy into electrical energy to provide electricity to the electricity-consuming device 30, and charge the supercapacitor 20. In the circumstance of no light, the supercapacitor 20 releases the stored electrical energy to maintain the operation of electricity-consuming device.

Besides, the photovoltaic module 1 of the present invention could further include a control unit 40, as shown in FIG. 4. The control unit is configured between the dye-sensitized solar cell 10 and the supercapacitor 20 to control their charging and discharging process and prevent the occurrence of reversed current, and therefore provides the module an excellent operation performance. The control unit 40 can be a diode or a power management IC.

With reference to the following disclosures combined with the accompanying embodiments and drawings, the photovoltaic module according to the present invention is illustrated and understood. It should be noted that the accompanying drawings are provided only for illustration where the size or scale of the elements shown therein are not necessarily the actual one.

### EXAMPLE

### Dye-Sensitized Solar Cell Clock

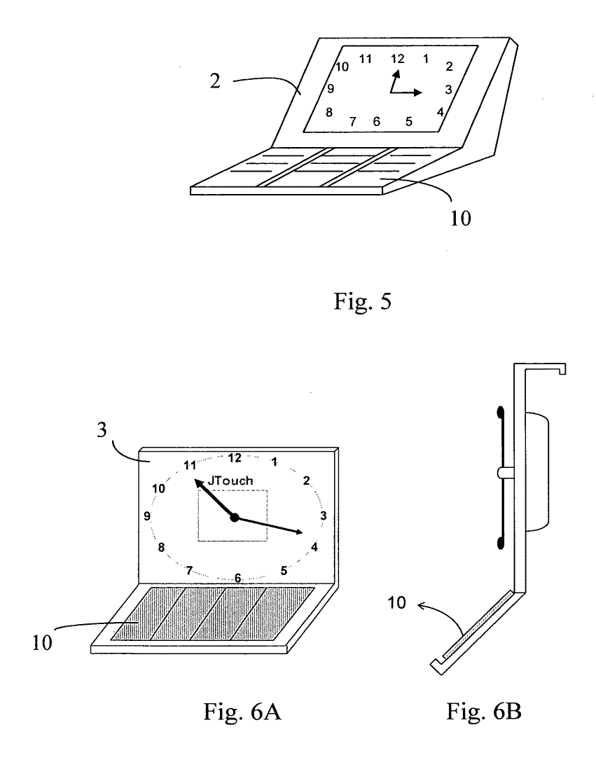

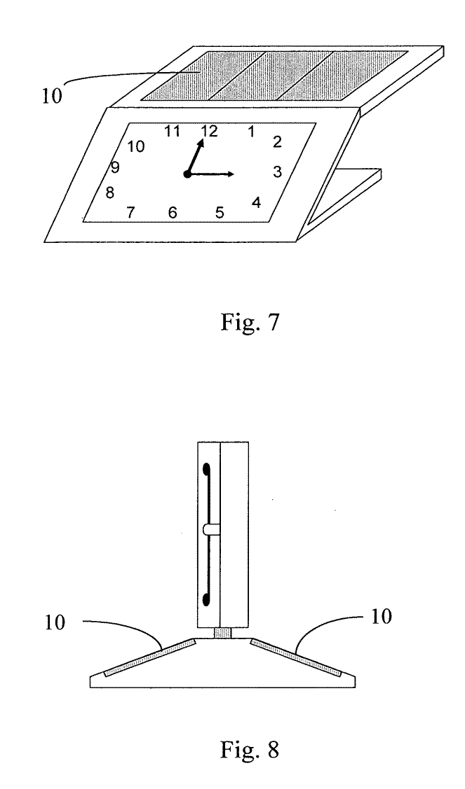

FIG. 5, FIG. 6A, FIG. 6B, FIG. 7 and FIG. 8 schematically illustrate various embodiments of dye-sensitized solar cell clock of the present invention. FIG. 5 shows a table clock 2, wherein the dye-sensitized solar cell 10 is configured on the base top of the table clock 2 for absorbing the light energy from table lamp or fluorescent lamp. Other types of table clock, such as the one shown in FIG. 7, can absorb the light from many sources, such as lamplight, sunlight coming in from the windows, and etc. FIG. 8 shows another type of table clock, which has a rotating shaft between the clock dial and the base. The dye-sensitized solar cell 10 is configured on both side of the base, to be suitable to be placed under table lamp or next to the window. The clock dial can be rotated to face any direction as needed.

FIG. 6A shows a wall clock 3, wherein dye-sensitized solar cell is configured on the other plane slightly tilting upward of the wall clock to absorb the light of indoor lamps. FIG. 6B is a side view of the wall clock 3.

For the above-mentioned clocks, in order to provide a best operation performance, a control unit 40 is further configured between the dye-sensitized solar cell 10 and the supercapacitor 20. The control unit 40 can be a diode or power management IC, which is used to control the charging and discharging process between the dye-sensitized solar cell 10 and supercapacitor 20 to prevent the occurrence of reversed current.

The movement of aforesaid clocks 2 and 3 are quartz movement, whose power source traditionally is alkaline battery of primary battery with the voltage of 1.5 volts. It has been proofed by experiments that the quartz movements can operate at the voltage of 1.0 to 2.5 volts. The voltage of each dye-sensitized solar cell 10 is about 0.5 to 0.7 volts. After appropriate series connection, the dye-sensitized solar cells 10 can generate a voltage suitable to be used in quartz movement. The rated voltage of supercapacitor 20 is 2.5 to 2.7 volts, and the capacity is 1.5 to 100 farads. Therefore, using dye-sensitized solar cell 10 and supercapacitor 20 can replace conventional primary batteries.

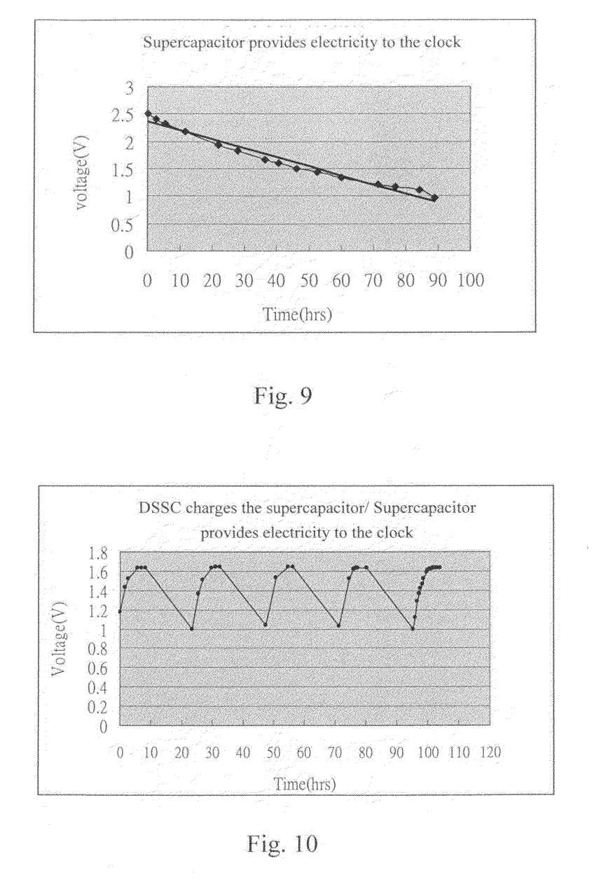

The energy stored in the supercapacitor 20 should be sufficient to maintain the operation of the clock during the period of no light. When fully charged, the supercapacitor 20 can continuously provide electricity to the clock independently for couple days, to overcome the problem of no electricity generated from the dye-sensitized solar cell 10. As shown in FIG. 9, supercapacitor 20 of 25 farads can provide electricity to the operation of clock for 90 hours. In the rooms with sufficient light intensity (about 400 lux), the clock can continuously operate unless in the circumstance of no light for a very long time. Only for the case of relying only on the supercapacitor 20 to provide electricity, it is possible for the clock to stop functioning. When the voltage of the supercapacitor 20 decreases as releasing electricity, but still higher than 1.0 volts, as long as the dye-sensitized solar cell 10 is exposed to light and transforms light energy into electrical energy, the dye-sensitized solar cell 10 can charge the supercapacitor 20, and the voltage of supercapacitor will increase accordingly. But if the voltage is lower than 1.0 volt, the clock might stop functioning. In this case, as long as a fully charged supercapacitor 20 is provided to replace the old one or exposing the clock to light for a period of time, the clock will continue to function again.

In a general indoor working place, lighting device is used during work. Therefore, dye-sensitized solar cell 10 can absorb the light energy of lighting device to provide electricity to the clock, and charge the supercapacitor 20 at the same time. At this time, the voltage of supercapacitor 20 increases. After work, the lighting device is shut off. The supercapacitor 20 will release the stored electrical energy to maintain the operation of clock, and the voltage decreases with the discharging process. As the beginning of work in the next day, the lighting device is switched on. The dye-sensitized solar cell 10 can function again to charge the supercapacitor 20. Cycling as such, the clock can continue to operate, as shown in FIG. 10, which is the testing data of five successive days. In FIG. 10, the supercapacitor 20 is charged by the dye-sensitized solar cell 10 to as high as 1.6 volts during daytime work. After work when the lighting device is shut off, the supercapacitor 20 provides electricity to the clock, and the voltage of the supercapacitor 20 decreases to about 1.0 volt. But in the next working day when the lighting device is switched on, the supercapacitor 20 is charged to 1.6 volts again. In the circumstance of weekends, as described above, the supercapacitor 20 of 25 farads can maintain the operation of clock alone for 90 hours without charging.

While the invention has been described in terms of what are presently considered to be the most practical and preferred embodiments, it is to be understood that the invention need not be limited to the disclosed embodiment. On the contrary, it is intended to cover various modifications and similar arrangements included within the spirit and scope of the appended claims, which are to be accorded with the broadest interpretation so as to encompass all such modifications and similar structures. Therefore, the above description and illustration should not be taken as limiting the scope of the present invention which is defined by the appended claims.

What is claimed is:

1. A photovoltaic module comprising:
a dye-sensitized solar cell;
a supercapacitor, which is electrically connected to said dye-sensitized solar cell to store the electrical energy generated therefrom; and
an electricity-consuming device, which is electrically connected to said dye-sensitized solar cell and said supercapacitor;
wherein, when exposed to light, said dye-sensitized solar cell absorbs the light energy to transform into electrical energy, part of said electrical energy is to provide the operation of said electricity-consuming device, and the other part of said electrical energy is stored in said supercapacitor; in the circumstance of no light, said supercapacitor releases the stored electrical energy to said electricity-consuming device to maintain the operation thereof.

2. The photovoltaic module of claim 1, wherein said dye-sensitized solar cell comprises a first electrode and a second electrode; said first electrode comprises a first conductive layer and a platinum catalyst layer; said first conductive layer comprises a first substrate and a first transparent conductive oxide to allow said platinum catalyst layer to adhere thereon; said second electrode comprises a second conductive layer and a nano layer; said second conductive layer comprises a second substrate and a second transparent conductive oxide; said nano layer comprises an optical semiconductor oxide, a plurality of dye molecules and electrolyte adhered on said optical semiconductor oxide.

3. The photovoltaic module of claim 2, wherein said first substrate and said second substrate is made of glass or flexible substrate.

4. The photovoltaic module of claim 3, wherein said flexible substrate is metal or polymer film.

5. The photovoltaic module of claim 4, wherein said metal is stainless steel or titanium alloy.

6. The photovoltaic module of claim 4, wherein said polymer film is PET or PEN.

7. The photovoltaic module of claim 1, wherein said light absorbed by said dye-sensitized solar cell is sun light.

8. The photovoltaic module of claim 1, wherein said light absorbed by said dye-sensitized solar cell is from lighting device.

9. The photovoltaic module of claim 1, wherein said electricity-consuming device includes clock, night lamp and calculator.

10. The photovoltaic module of claim 1 further includes a control unit, which is configured between said dye-sensitized solar cell and said supercapacitor to control the charging and discharging process thereof.

11. The photovoltaic module of claim 7, wherein said control unit is a diode or a power management IC.

12. A clock using photovoltaic module comprises:
a dye-sensitized solar cell;
a supercapacitor, which is electrically connected to said dye-sensitized solar cell to store the energy generated therefrom; and
a clock, which is electrically connected to said dye-sensitized solar cell and said supercapacitor;
wherein, when exposed to light, said dye-sensitized solar cell absorbs the light energy to transform into electrical energy, part of said electrical energy is to provide the operation of said clock, and the other part of said electrical energy is stored in said supercapacitor; in the circumstance of no light, said supercapacitor releases the stored electrical energy to said clock to maintain the operation thereof.

13. The clock using photovoltaic module of claim 12, wherein said dye-sensitized solar cell comprises a first electrode and a second electrode; said first electrode comprises a first conductive layer and a platinum catalyst layer; said first conductive layer comprises a first substrate and a first transparent conductive oxide to allow said platinum catalyst layer to adhere thereon; said second electrode comprises a second conductive layer and a nano layer; said second conductive layer comprises a second substrate and a second transparent conductive oxide; said nano layer comprises an optical semiconductor oxide, a plurality of dye molecules and electrolyte adhered on said optical semiconductor oxide.

14. The clock using photovoltaic module of claim 13, wherein said first substrate and said second substrate is made of glass or flexible substrate.

15. The clock using photovoltaic module of claim 14, wherein said flexible substrate is metal or polymer film.

16. The clock using photovoltaic module of claim 15, wherein said metal is stainless steel or titanium alloy.

17. The clock using photovoltaic module of claim 15, wherein said polymer film is PET or PEN.

18. The clock using photovoltaic module of claim 12, wherein said light absorbed by said dye-sensitized solar cell is sun light.

19. The clock using photovoltaic module of claim 12, wherein said light absorbed by said dye-sensitized solar cell is from lighting device.

20. The clock using photovoltaic module of claim 12 further includes a control unit, which is configured between said dye-sensitized solar cell and said supercapacitor to control the charging and discharging process thereof.

21. The clock using photovoltaic module of claim 20, wherein said control unit is a diode or power management IC.
